(19) United States
(12) Patent Application Publication
(10) Pub. No.: US 2026/0245794 A1
(43) Pub. Date: Aug. 20, 2026

(54) ELECTRONIC COMPONENT AND MODULE

(71) Applicant: TDK Corporation, Tokyo (JP)

(72) Inventors: Yuuki ABURAKAWA, Tokyo (JP); Hironori Sato, Tokyo (JP); Mitsunori Hiraoka, Tokyo (JP)

(73) Assignee: TDK Corporation, Tokyo (JP)

(21) Appl. No.: 19/540,063

(22) Filed: Feb. 13, 2026

(30) Foreign Application Priority Data
Feb. 20, 2025 (JP) 2025-025758

(51) Int. Cl. H01G 4/012; H01G 4/232; H01G 4/30

(52) U.S. Cl. CPC H01G 4/012; H01G 4/232; H01G 4/2325; H01G 4/30

(57) ABSTRACT

In an electronic component, a main surface of a lower conductive layer in an outer peripheral region is exposed from a protective layer. Therefore, when the electronic component is incorporated into a circuit board, the main surface directly contacts an interlayer resin of the circuit board. Since the main surface of the lower conductive layer in the outer peripheral region is a roughened surface, improvement in adhesion between the interlayer resin and the lower conductive layer is achieved, and high adhesion between the electronic component and the interlayer resin of the circuit board is realized.

### CROSS-REFERENCE TO RELATED APPLICATIONS

This application is based upon and claims the benefit of priority from Japanese Patent Application No. 2025-25758, filed on 20 February, 2025, the entire contents of which are incorporated herein by reference.

### TECHNICAL FIELD

The present disclosure relates to an electronic component and a module.

### BACKGROUND

PCT international publication WO2022/158340 discloses a configuration in which an electronic component including a capacitor structure is mounted on a substrate.

### SUMMARY

The inventors have repeatedly conducted research on a technology for incorporating an electronic component as described above into a module such as a circuit board, and at the incorporation, it is conceivable to embed the electronic component in an interlayer resin material of the module.

The inventors, as a result of diligent research, have newly found a technology that can enhance the adhesion between an electronic component and an interlayer resin material of a module when incorporating the electronic component into the module.

According to various aspects of the present disclosure, an electronic component and a module with adhesion improved in incorporating the electronic component into the module are provided.

An electronic component according to one aspect of the present disclosure comprises a lower conductive layer having a main surface, and, when viewed from the main surface side, having an outer peripheral region located at an outer edge, an inner peripheral region located on an inner peripheral side of the outer peripheral region, and a capacitor region surrounded by the inner peripheral region. A dielectric layer and an upper conductive layer are arranged in order on the lower conductive layer in the capacitor region. A resin layer integrally covers the dielectric layer and the upper conductive layer in the capacitor region and the lower conductive layer exposed from the dielectric layer and the upper conductive layer in the inner peripheral region. An arithmetic mean roughness of the lower conductive layer in the outer peripheral region is greater than an arithmetic mean roughness of the lower conductive layer in the capacitor region.

Further, an electronic component according to another aspect of the present disclosure comprises a lower conductive layer having a main surface, and, when viewed from the main surface side, having an outer peripheral region located at an outer edge, an inner peripheral region located on an inner peripheral side of the outer peripheral region, and a capacitor region surrounded by the inner peripheral region. A dielectric layer and an upper conductive layer are arranged in order on the lower conductive layer in the capacitor region. A resin layer integrally covers the dielectric layer and the upper conductive layer in the capacitor region and the lower conductive layer exposed from the dielectric layer and the upper conductive layer in the inner peripheral region. The lower conductive layer has a protrusion on the main surface in the outer peripheral region.

Furthermore, a module according to one aspect of the present disclosure includes the above electronic component.

### BRIEF DESCRIPTION OF THE DRAWINGS

FIG. 1 is a schematic cross-sectional view showing a circuit board according to an embodiment.

FIG. 2 is a schematic plan view of the electronic component shown in FIG. 1.

FIG. 3 is a cross-sectional view of the electronic component shown in FIG. 2, taken along line III-III.

FIG. 4 is an enlarged view of a main part of FIG. 3.

FIG. 5 is an enlarged view of a main part showing a state of a main surface of a lower conductive layer.

FIG. 6 is an enlarged view of a main part showing a state of a main surface of a lower conductive layer different from that of FIG. 5.

FIG. 7 is a cross-sectional view showing an electronic component in a form different from that of FIG. 4.

FIG. 8 is a cross-sectional view showing an electronic component in a form different from that of FIG. 4.

FIG. 9 is a cross-sectional view showing an electronic component in a form different from that of FIG. 4.

FIG. 10 is a plan view showing an electronic component in a form different from that of FIG. 2.

### DETAILED DESCRIPTION

Hereinafter, embodiments of the present disclosure will be described in detail with reference to the accompanying drawings. In the description of the drawings, the same or corresponding elements are denoted by the same reference numerals, and redundant description thereof will be omitted.

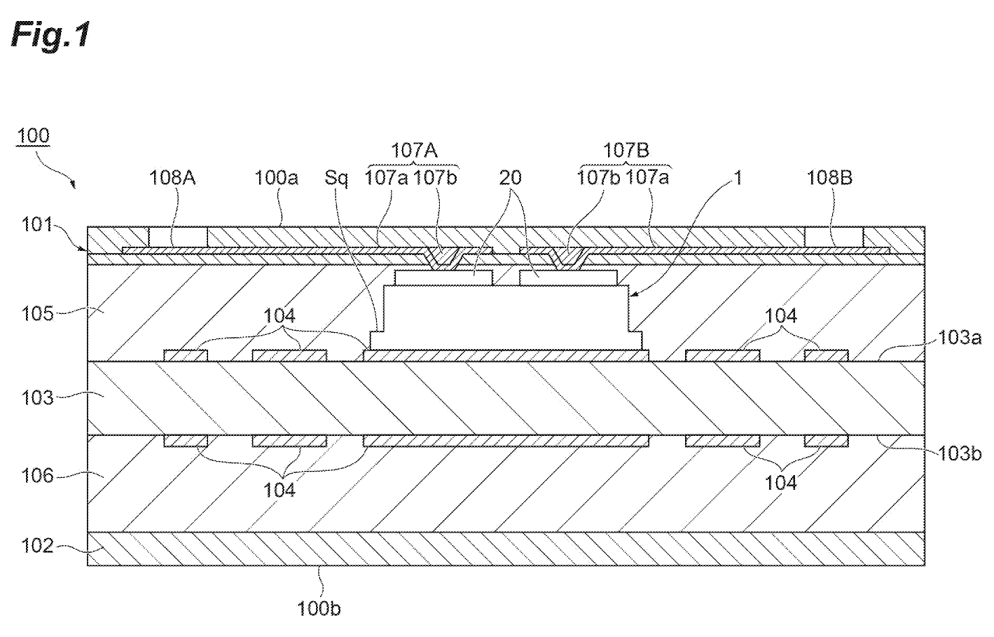

A circuit board 100 according to an embodiment will be described with reference to FIG. 1. The circuit board 100 is a type of module and has a flexible sheet-like or plate-like shape. The circuit board 100 according to the present embodiment has, for example, a rectangular sheet shape of 180mm × 180mm. The circuit board 100 has a pair of main surfaces 100a and 100b that face each other in a thickness direction. One main surface 100a is constituted by a surface layer 101, and the other main surface 100b is constituted by a surface layer 102. Both the surface layers 101 and 102 are constituted by an insulating material (for example, a polyimide-based resin or an epoxy-based resin).

The circuit board 100 includes a core substrate 103 in its interior. The core substrate 103 extends parallel to the main surfaces 100a and 100b. The core substrate 103 has a plurality of terminals 104 (or wirings) patterned on a main surface 103a on the main surface 100a side of the circuit board 100 and a main surface 103b on the main surface 100b side of the circuit board 100. In the present embodiment, an electronic component 1 described later is mounted on the terminals 104 provided on the main surface 103a of the core substrate 103. The electronic component 1 is located between the core substrate 103 and the surface layer 101. An interlayer resin 105 is also disposed between the core substrate 103 and the surface layer 101, and the interlayer resin 105 surrounds the electronic component 1. A constituent material of the interlayer resin 105 is, for example, a polyimide-based resin or an epoxy-based resin. Similarly, an interlayer resin 106 is also disposed between the core substrate 103 and the surface layer 102. A constituent material of the interlayer resin 106 is, for example, a polyimide-based resin or an epoxy-based resin and may be the same as or different from the constituent material of the interlayer resin 105. The interlayer resins 105 and 106 may include a filler, and silica can be used as the filler.

The surface layer 101 includes a pair of redistribution portions 107A and 107B for respectively drawing out a pair of external electrodes 20 of the electronic component 1. In the present embodiment, the surface layer 101 has a multilayer structure, and each of the redistribution portions 107A and 107B includes an electrode lead-out layer 107a that extends parallel to the main surfaces 100a and 100b between layers of the surface layer 101, and a via conductor 107b that extends from the electrode lead-out layer 107a along the thickness direction of the circuit board 100 to the external electrodes 20 of the electronic component 1. The redistribution portion 107A is electrically connected to one external electrode 20 of the electronic component 1 and constitutes an external connection terminal 108A at a portion of the electrode lead-out layer 107a exposed from the surface layer 101. The redistribution portion 107B is electrically connected to the other external electrode 20 of the electronic component 1 and constitutes an external connection terminal 108B at a portion of the electrode lead-out layer 107a exposed from the surface layer 101. On the main surface 100a of the circuit board 100, various electronic chips such as a CPU can be mounted by providing solder bumps or the like on the external connection terminals 108A and 108B.

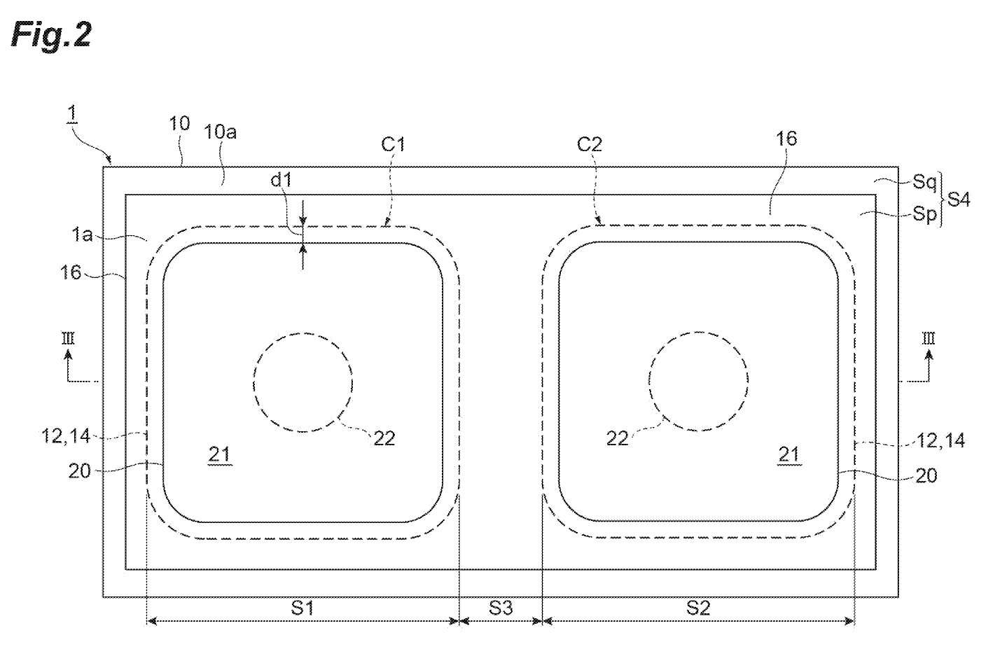

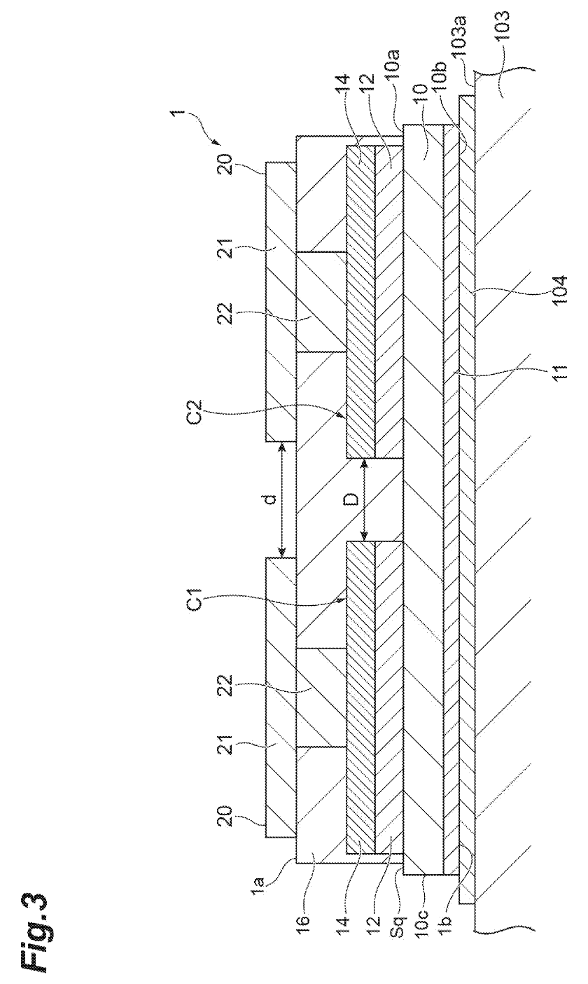

Next, a configuration of the electronic component 1 embedded in the circuit board 100 will be described with reference to FIGS. 2 and 3. The electronic component 1 has a sheet-like shape and has a thickness of, for example, 50μm or less (40μm as an example). The electronic component 1 has a pair of main surfaces 1a and 1b that face each other in the thickness direction of the circuit board 100. One main surface 1a is located on the main surface 100a side of the circuit board 100, and the other main surface 1b is located on the main surface 100b side of the circuit board 100. Hereinafter, for convenience of description, one main surface 1a of the electronic component 1 is also referred to as a first main surface, and the other main surface 1b is also referred to as a second main surface.

As shown in FIG. 2, the electronic component 1 is provided with a first capacitor region S1 and a second capacitor region S2 when viewed from the first main surface 1a side. Capacitor structures C1 and C2 are respectively formed in the first capacitor region S1 and the second capacitor region S2. When viewed from the first main surface 1a side, the first capacitor region S1 and the second capacitor region S2 are arranged apart by a predetermined distance D, and an intermediate region S3 interposed between the first capacitor region S1 and the second capacitor region S2 is provided. That is, when viewed from the first main surface 1a side, the first capacitor region S1 and the second capacitor region S2 are indirectly adjacent to each other via the intermediate region S3.

As shown in FIG. 3, both the capacitor structure C1 of the first capacitor region S1 and the capacitor structure C2 of the second capacitor region S2 are configured to include a lower conductive layer 10, a dielectric layer 12, and an upper conductive layer 14.

The lower conductive layer 10 is provided over the entire area of the electronic component 1 including the first capacitor region S1, the second capacitor region S2, and the intermediate region S3, when viewed from the first main surface 1a side. The lower conductive layer 10 extends so as to straddle the first capacitor region S1, the second capacitor region S2, and the intermediate region S3, when viewed from the first main surface 1a side. The lower conductive layer 10 according to the present embodiment has a shape extending in one direction (that is, a direction in which the first capacitor region S1 and the second capacitor region S2 are arranged) and has a rectangular shape. The rectangular shape in this specification also includes a rectangular shape with rounded corners and a rectangular shape with chamfered corners. Further, the lower conductive layer 10 may have a polygonal shape other than a rectangle or may have a circular or elliptical shape. A dielectric layer 12 and an upper conductive layer 14 are formed on one main surface 10a (upper surface) of the lower conductive layer 10, and the other main surface 10b (lower surface) located on the opposite side of the main surface 10a constitutes the second main surface 1b of the electronic component 1. The lower conductive layer 10 can be constituted by a metal foil, and in the present embodiment, is constituted by a Ni foil. For the metal foil, for example, a Ni-based alloy foil, a Cu foil, or a Cu-based alloy foil can be adopted in addition to the Ni foil. By constituting the lower conductive layer 10 with a metal foil, sufficient strength and rigidity can be ensured, and it can be handled as a self-supporting substrate. The lower conductive layer 10 can be constituted by a single layer or a plurality of layers.

In the first capacitor region S1, the dielectric layer 12 and the upper conductive layer 14 are stacked in this order on the lower conductive layer 10. In the present embodiment, the dielectric layer 12 is directly stacked on the lower conductive layer 10, and the upper conductive layer 14 is directly stacked on the dielectric layer 12. The dielectric layer 12 has a side surface 12a extending parallel to a stacking direction, and the side surface 12a constitutes an outer shape of the dielectric layer 12 when viewed from the first main surface 1a side. Similarly, the upper conductive layer 14 has a side surface 14a extending parallel to the stacking direction, and the side surface 14a constitutes an outer shape of the upper conductive layer 14 when viewed from the first main surface 1a side. In the present embodiment, the side surface 12a of the dielectric layer 12 and the side surface 14a of the upper conductive layer 14 are flush with each other. Further, in the present embodiment, when viewed from the first main surface 1a side, the outer shape of the dielectric layer 12 and the outer shape of the upper conductive layer 14 are identical with each other as a whole. When viewed from the first main surface 1a side, the outer shape of the dielectric layer 12 and the outer shape of the upper conductive layer 14 may be identical with each other as a whole or may be identical with each other partially, and the mode of identification includes not only a mode in which both are identical strictly, but also a mode including a deviation amount within ±1% with respect to the total length of the dielectric layer 12 or the total length of the upper conductive layer 14. Such a deviation includes, for example, a minute difference within a preset range or a manufacturing error.

In the present embodiment, when viewed from the first main surface 1a side, both the outer shape of the dielectric layer 12 and the outer shape of the upper conductive layer 14 have a square shape. The square shape in this specification also includes a square shape with rounded corners and a square shape with chamfered corners. Further, the outer shape of the dielectric layer 12 and the outer shape of the upper conductive layer 14 may have a polygonal shape other than a square, or may have a circular or elliptical shape. In the present embodiment, when viewed from the first main surface 1a side, an outer edge of the first capacitor region S1 is constituted by an outer edge of the capacitor structure C1, and specifically, is constituted by an outer edge of the dielectric layer 12 and an outer edge of the upper conductive layer 14 that constitute the capacitor structure C1.

The dielectric layer 12 can be constituted by, for example, a ceramic dielectric (for example, barium titanate). The dielectric layer 12 can be constituted by a sputtered layer. As a constituent material of the dielectric layer 12, in addition to barium titanate, other dielectrics having a perovskite-type crystal structure or dielectrics having a tungsten bronze-type crystal structure can be adopted. The upper conductive layer 14 can be constituted by a metal layer (for example, a Ni sputtered layer). As a constituent material of the upper conductive layer 14, in addition to Ni, a Ni-based alloy, Cu, or a Cu-based alloy can be adopted.

In the second capacitor region S2, similarly to the first capacitor region S1, the dielectric layer 12 and the upper conductive layer 14 are stacked in this order on the lower conductive layer 10. In the present embodiment, various dimensions (for example, outer dimensions and thickness dimensions) of the dielectric layer 12 and the upper conductive layer 14 in the second capacitor region S2 are the same as the respective various dimensions of the dielectric layer 12 and the upper conductive layer 14 in the first capacitor region S1. The mode of identification includes not only a mode in which the dielectric layer 12 and the upper conductive layer 14 in the first capacitor region S1 and the dielectric layer 12 and the upper conductive layer 14 in the second capacitor region S2 are identical strictly, but also a mode including, for example, a deviation amount within ±1% with respect to the total length of the dielectric layer 12 and the total length of the upper conductive layer 14 in the first capacitor region S1. Such a deviation includes, for example, a minute difference within a preset range or a manufacturing error. Further, regarding the constituent materials, the dielectric layer 12 and the upper conductive layer 14 in the second capacitor region S2 are the same as the dielectric layer 12 and the upper conductive layer 14 in the first capacitor region S1.

As shown in FIG. 2, the first capacitor region S1 and the second capacitor region S2 are separated from an outer edge of the lower conductive layer 10 by a predetermined distance, and an exposed region S4 where the lower conductive layer 10 is exposed from the dielectric layer 12 and the upper conductive layer 14 is formed at the outer edge of the lower conductive layer 10. More specifically, both the first capacitor region S1 and the second capacitor region S2 are entirely separated from the outer edge of the lower conductive layer 10, and the exposed region S4 completely surrounds the first capacitor region S1 and the second capacitor region S2. The exposed region S4 includes an outer peripheral region Sq located at the outer edge of the lower conductive layer 10, and an inner peripheral region Sp located on an inner peripheral side of the outer peripheral region Sq.

The electronic component 1 includes a protective layer 16 (resin layer) that covers the entire surface when viewed from the first main surface 1a side. The protective layer 16 can be constituted by, for example, a polyimide-based resin or an epoxy-based resin. In the present embodiment, the protective layer 16 integrally covers the first capacitor region S1 and the second capacitor region S2. At this time, the protective layer 16 integrally covers the dielectric layer 12 and the upper conductive layer 14 in the first capacitor region S1, and the dielectric layer 12 and the upper conductive layer 14 in the second capacitor region S2. The protective layer 16 also includes a portion surrounding the first capacitor region S1 and the second capacitor region S2 when viewed from the first main surface 1a side and covers the side surface 12a of the dielectric layer 12 and the side surface 14a of the upper conductive layer 14 of each of the first capacitor region S1 and the second capacitor region S2. The protective layer 16 may cover the dielectric layer 12 and the upper conductive layer 14 directly or indirectly.

The protective layer 16 integrally covers the intermediate region S3 in addition to the first capacitor region S1 and the second capacitor region S2, when viewed from the first main surface 1a side. In the intermediate region S3, the protective layer 16 covers the lower conductive layer 10 exposed from the dielectric layer 12 and the upper conductive layer 14.

Further, the protective layer 16 also integrally covers the inner peripheral region Sp in addition to the first capacitor region S1, the second capacitor region S2, and the intermediate region S3, when viewed from the first main surface 1a side. In the inner peripheral region Sp, the protective layer 16 covers the lower conductive layer 10 exposed from the dielectric layer 12 and the upper conductive layer 14.

In the protective layer 16, external electrodes 20 are provided in each of the first capacitor region S1 and the second capacitor region S2. Specifically, the external electrodes 20 are provided through the protective layer 16 in portions on the upper conductive layer 14 of each of the first capacitor region S1 and the second capacitor region S2 and are electrically connected to the upper conductive layer 14. The external electrodes 20 can be constituted by, for example, Cu. In the present embodiment, each external electrode 20 is configured to include a main body portion 21 located on the protective layer 16, and a connection portion 22 extending from the main body portion 21 through the protective layer 16 to the upper conductive layer 14.

The main body portion 21 of each external electrode 20 has a substantially square outer shape when viewed from the first main surface 1a side. As shown in FIG. 1, the main body portion 21 of each external electrode 20 is designed to be slightly smaller than the capacitor structures C1 and C2 when viewed from the first main surface 1a side, and outer edges of the dielectric layer 12 and the upper conductive layer 14 are exposed from the main body portion 21. Therefore, as shown in FIG. 2, a separation distance d between the main body portion 21 of the external electrode 20 in the first capacitor region S1 and the main body portion 21 of the external electrode 20 in the second capacitor region S2 is longer than a separation distance D between the dielectric layer 12 and the upper conductive layer 14 of the capacitor structure C1 in the first capacitor region S1 and the dielectric layer 12 and the upper conductive layer 14 of the capacitor structure C2 in the second capacitor region S2. The separation distance D between the capacitor structure C1 in the first capacitor region S1 and the capacitor structure C2 in the second capacitor region S2 can be designed to be relatively long, and for example, can be designed to be longer than a distance d1 between an outer edge of the external electrode 20 and outer edges of the capacitor structures C1 and C2 when viewed from the first main surface 1a side.

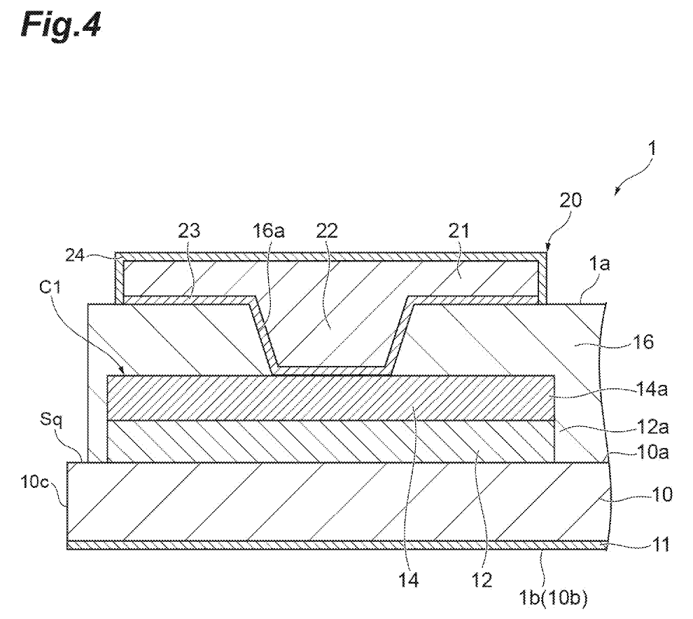

As shown in FIG. 4, the main body portion 21 of each external electrode 20 can include a surface layer 24. The surface layer 24 can be constituted by a single layer or a plurality of layers, and a top surface layer can be constituted by a material containing Au as a main component. For example, when the surface layer 24 is constituted by three layers, it can be a combination of an Au plating layer, a Pd plating layer, and a Ni plating layer arranged in order from the surface side. By constituting the surface layer 24 of the main body portion 21 of the external electrode 20 with a material containing Au as a main component, it is possible to reliably connect, for example, to a bonding wire connected to the external electrode 20.

The connection portion 22 of each external electrode 20 has a substantially perfect circular outer shape when viewed from the first main surface 1a side. A diameter of the connection portion 22 is designed to be narrower than a width of the main body portion 21 when viewed from the first main surface 1a side. By designing the connection portion 22 to be narrow in this way, a sufficient contact area between the protective layer 16 and the upper conductive layer 14 can be ensured, and improvement in adhesion between the protective layer 16 and the upper conductive layer 14 is achieved. Each connection portion 22 is located at the center of the first capacitor region S1 and the second capacitor region S2 when viewed from the first main surface 1a side and is connected to the upper conductive layer 14 at a center position of the upper conductive layer 14.

In the present embodiment, as shown in FIG. 4, a side surface 16a of the protective layer 16 is inclined with respect to the stacking direction. In this case, a cross-sectional dimension of each connection portion 22 in a cross-section orthogonal to the stacking direction gradually decreases as the distance from the main body portion 21 increases, and a width thereof gradually narrows in the cross-section shown in FIG. 4. Such an inclination of the side surface 16a of the protective layer 16 can be formed in patterning of the protective layer 16 (for example, dry etching to form a through-hole in which the connection portion 22 is provided). Since the side surface 16a of the protective layer 16 is inclined, an area of the side surface 16a is increased compared to a case where it is not inclined, and thereby improvement in adhesion between the protective layer 16 and the external electrode 20 is achieved.

Each external electrode 20 can be formed by electrolytic plating. In this case, as shown in FIG. 4, each external electrode 20 includes a seed layer 23 (underlayer) at an interface with the protective layer 16 and the upper conductive layer 14. The seed layer 23 may be constituted by the same material as a metal material (Cu) constituting the external electrode 20 or may be constituted by a different material. The seed layer 23 can be constituted by a single layer or a plurality of layers, and for example, in the case of two layers, a combination of a Cr sputtered layer and a Cu sputtered layer can be adopted. For the material of the seed layer 23, a material having relatively high adhesion to the protective layer 16 and the upper conductive layer 14 is adopted, and thereby the external electrode 20 has high adhesion to the protective layer 16 and the upper conductive layer 14.

As described above, the electronic component 1 includes the two capacitor structures C1 and C2, and these capacitor structures C1 and C2 can be used by being connected in parallel. In this case, the second main surface 1b of the electronic component 1 serves as a mounting surface to be mounted on the core substrate 103, and at that time, the lower conductive layer 10 located on the second main surface 1b is used as an external terminal. When the lower conductive layer 10 is used as an external terminal, as shown in FIGS. 3 and 4, the lower conductive layer 10 can include a surface layer 11 that constitutes the second main surface 1b of the electronic component 1. The surface layer 11 can be constituted by a single layer or a plurality of layers, and a top surface layer can be constituted by a material containing Au as a main component. For example, when the surface layer 11 is constituted by three layers, it can be a combination of an Au plating layer, a Pd plating layer, and a Ni plating layer arranged in order from the surface side. By constituting the surface layer 11 of the lower conductive layer 10 with a material containing Au as a main component, it is possible to reliably connect, for example, to the terminals 104 of the core substrate 103 connected to the lower conductive layer 10.

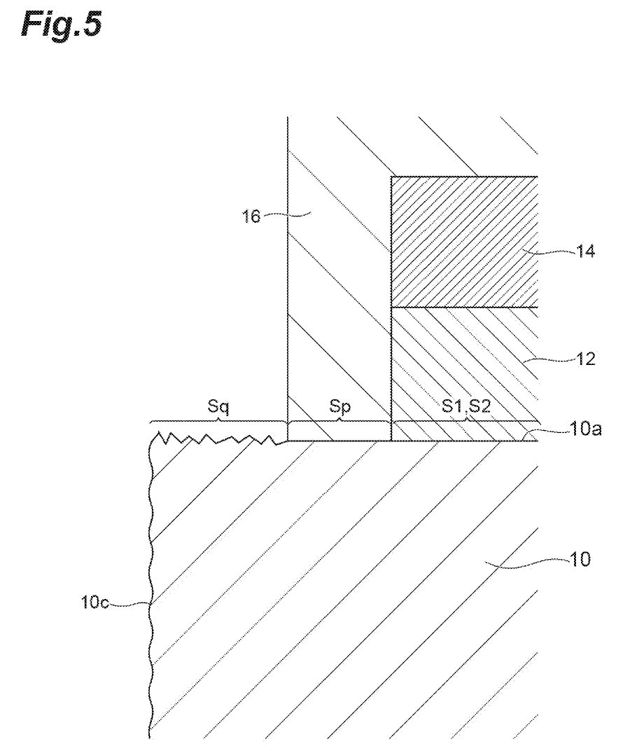

Here, a surface state of the main surface 10a of the lower conductive layer 10 will be described with reference to FIG. 5. In the vicinity of the outer edge of the lower conductive layer 10, an outer peripheral region Sq, an inner peripheral region Sp, and capacitor regions S1 and S2 (a first capacitor region or a second capacitor region) are arranged adjacently in order from the outside. The main surface 10a of the lower conductive layer 10 in the outer peripheral region Sq is a roughened surface and has a relatively large surface roughness (arithmetic mean roughness Ra). Specifically, the arithmetic mean roughness of the main surface 10a of the lower conductive layer 10 in the outer peripheral region Sq is greater than the arithmetic mean roughness of the main surface 10a of the lower conductive layer 10 in the inner peripheral region Sp and the capacitor regions S1 and S2. As an example, the arithmetic mean roughness Ra1 in the outer peripheral region Sq is 200nm to 5000nm (for example, 800nm), the arithmetic mean roughness Ra2 in the capacitor regions S1 and S2 is 1 to 20nm, and the arithmetic mean roughness Ra3 in the inner peripheral region Sp is 1 to 3000nm. In the present embodiment, a ratio of the arithmetic mean roughness Ra1 to the arithmetic mean roughness Ra2 (Ra1/Ra2) is 10 < Ra1/Ra2 < 5000, and as an example, Ra1/Ra2 is 400. In the present embodiment, a ratio of the arithmetic mean roughness Ra1 to the arithmetic mean roughness Ra3 (Ra1/Ra3) is 1/15 < Ra1/Ra3 < 5000, and as an example, Ra1/Ra3 is 400. The arithmetic mean roughness Ra2 in the capacitor regions S1 and S2 and the arithmetic mean roughness Ra3 in the inner peripheral region Sp may be the same or different. When the arithmetic mean roughness Ra2 in the capacitor regions S1 and S2 and the arithmetic mean roughness Ra3 in the inner peripheral region Sp are different, a ratio of the arithmetic mean roughness Ra2 to the arithmetic mean roughness Ra3 (Ra2/Ra3) is 1/3000 < Ra2/Ra3 < 20, and as an example, Ra2/Ra3 is 1/1500.

In the electronic component 1, the main surface 10a of the lower conductive layer 10 in the outer peripheral region Sq is exposed from the protective layer 16. Therefore, when the electronic component 1 is incorporated into the circuit board 100 shown in FIG. 1, the outer peripheral region Sq of the main surface 10a of the lower conductive layer 10 directly contacts the interlayer resin 105 surrounding the electronic component 1. As described above, since the main surface 10a of the lower conductive layer 10 in the outer peripheral region Sq is a roughened surface, improvement in adhesion between the interlayer resin 105 and the lower conductive layer 10 is achieved due to an increase in adhesion area, an anchor effect, and the like, compared to a case of a smooth flat surface. By enhancing the adhesion between the interlayer resin 105 and the lower conductive layer 10 in this way, high adhesion between the electronic component 1 and the interlayer resin 105 of the circuit board 100 is realized.

The arithmetic mean roughness Ra1 of the main surface 10a of the lower conductive layer 10 in the outer peripheral region Sq may be substantially uniform over the entire circumference of the outer edge of the lower conductive layer 10 or may be locally large or small. For example, when viewed from the first main surface 1a side, the arithmetic mean roughness Ra1 of a corner portion of the outer peripheral region Sq corresponding to a corner portion of the rectangular lower conductive layer 10 may be locally larger than that of other portions.

In the electronic component 1 described above, the protective layer 16 that covers the dielectric layer 12 and the upper conductive layer 14 in the first capacitor region S1 and the second capacitor region S2 also covers the lower conductive layer 10 in the intermediate region S3. That is, the protective layer 16 and the lower conductive layer 10 are in direct contact, and thereby the adhesion of the protective layer 16 is improved, so that insulation from the outside can be more reliably achieved.

Further, the protective layer 16 also covers the lower conductive layer 10 in the inner peripheral region Sp, and since the protective layer 16 and the lower conductive layer 10 are in direct contact also in the exposed region S4, the adhesion of the protective layer 16 is further improved.

The wider the intermediate region S3 and the inner peripheral region Sp are, the more the adhesion of the protective layer 16 can be improved, and for example, the longer the separation distance D between the dielectric layer 12 and the upper conductive layer 14 in the first capacitor region S1 and the dielectric layer 12 and the upper conductive layer 14 in the second capacitor region S2 is, the more the adhesion of the protective layer 16 can be improved.

In the electronic component 1 described above, insulation between the lower conductive layer 10 and the upper conductive layer 14 is achieved by the protective layer 16 located in the same layer as the dielectric layer 12. Further, stray capacitance due to a potential difference between the lower conductive layer 10 and the upper conductive layer 14 may occur in the protective layer 16 located in the same layer as the dielectric layer 12. Therefore, by constituting the protective layer 16 with a material having a relatively low dielectric constant, the stray capacitance can be suppressed.

In the present embodiment, an end face 10c extending in the thickness direction of the lower conductive layer 10 is also a roughened surface and has a relatively large surface roughness (arithmetic mean roughness Ra). Specifically, the arithmetic mean roughness of the end face 10c is greater than the arithmetic mean roughness in the inner peripheral region Sp and the capacitor regions S1 and S2. The arithmetic mean roughness of the end face 10c may be greater than the arithmetic mean roughness in the inner peripheral region Sp and the capacitor regions S1 and S2, and may be smaller than the arithmetic mean roughness in the outer peripheral region Sq. As an example, the arithmetic mean roughness Ra4 of the end face 10c of the lower conductive layer 10 is 200nm to 5000nm (for example, 800nm). In the present embodiment, a ratio of the arithmetic mean roughness Ra4 to the arithmetic mean roughness Ra1 (Ra4/Ra1) is 0.04 < Ra4/Ra1 < 25, and as an example, Ra4/Ra1 is 1. Further, a ratio of the arithmetic mean roughness Ra4 to the arithmetic mean roughness Ra3 (Ra4/Ra3) is 1/15 < Ra4/Ra3 < 5000, and as an example, Ra4/Ra3 is 400. When the arithmetic mean roughness Ra2 in the capacitor regions S1 and S2 and the arithmetic mean roughness Ra3 in the inner peripheral region Sp are different, a ratio of the arithmetic mean roughness Ra4 to the arithmetic mean roughness Ra2 (Ra4/Ra2) is 10 < Ra4/Ra2 < 5000, and as an example, Ra4/Ra2 is 400. The end face 10c of the lower conductive layer 10 is, for example, a cut surface when a sheet-like conductor serving as a base of the lower conductive layer 10 is diced into the size of the lower conductive layer 10. When a laser is used for cutting, the end face 10c is a laser-cut surface. When the electronic component 1 is incorporated into the circuit board 100, the end face 10c of the lower conductive layer 10 directly contacts the interlayer resin 105 surrounding the electronic component 1. Since the end face 10c of the lower conductive layer 10 is a roughened surface, improvement in adhesion between the interlayer resin 105 and the lower conductive layer 10 is achieved due to an increase in adhesion area, an anchor effect, and the like, compared to a case of a smooth flat surface, and further improvement in adhesion between the electronic component 1 and the interlayer resin 105 of the circuit board 100 is achieved.

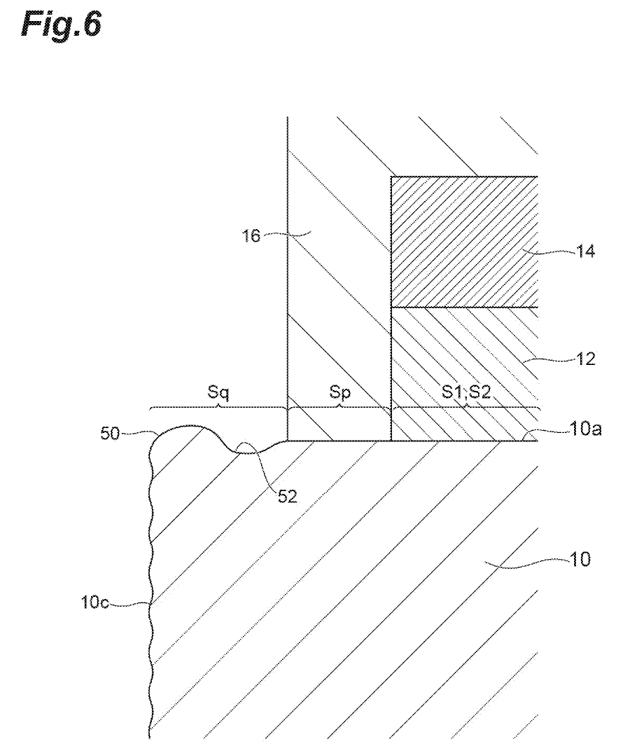

As shown in FIG. 6, even when protrusions 50 are provided on the main surface 10a of the lower conductive layer 10 in the outer peripheral region Sq, improvement in adhesion between the interlayer resin 105 and the lower conductive layer 10 can be achieved. The number of protrusions 50 may be one or more. The protrusions 50 may be formed along the entire circumference of the outer edge of the lower conductive layer 10 over the entire circumference of the outer peripheral region Sq or may be formed intermittently along the outer edge of the lower conductive layer 10. Recesses 52 may be further provided on the main surface 10a of the lower conductive layer 10 in the outer peripheral region Sq, and in this case, the protrusions 50 and the recesses 52 are mixed in the outer peripheral region Sq. In the present embodiment, a height of the protrusion 50 is 1μm to 6μm, and is 3.4μm as an example. The height of the protrusion 50 may be substantially uniform over the entire circumference of the outer edge of the lower conductive layer 10 or may be locally high or low. For example, when viewed from the first main surface 1a side, the height of the protrusion 50 at a corner portion of the outer peripheral region Sq corresponding to a corner portion of the rectangular lower conductive layer 10 may be locally higher than that of other portions. Further, a depth of the recess 52 is 1μm to 6μm, and is 3.5μm as an example.

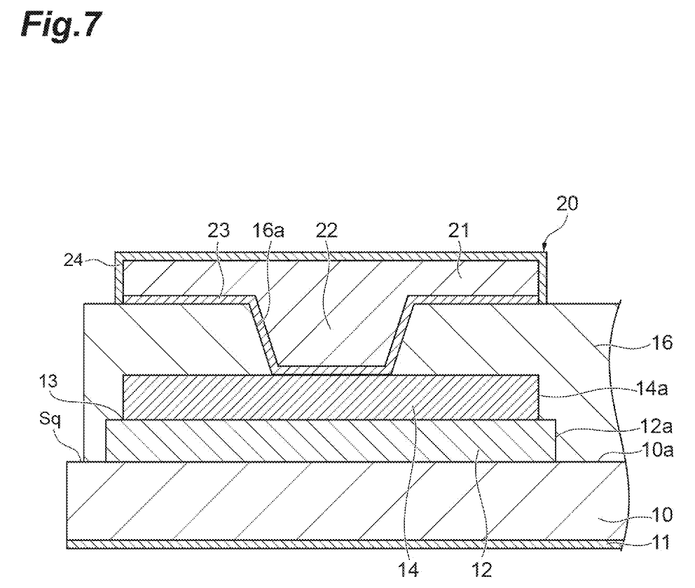

The dielectric layer 12 and the upper conductive layer 14 constituting the capacitor structures C1 and C2 are not limited to the form shown in FIG. 4, and may have the forms shown in FIGS. 7 to 9.

In the form shown in FIG. 7, both the side surface 12a of the dielectric layer 12 and the side surface 14a of the upper conductive layer 14 extend parallel to the stacking direction, and the side surface 12a of the dielectric layer 12 protrudes with respect to the side surface 14a of the upper conductive layer 14. In this case, when viewed from the first main surface 1a side, an outer edge of the dielectric layer 12 is located outside an outer edge of the upper conductive layer 14, and the outer edge of the dielectric layer 12 constitutes an outer edge of the capacitor structures C1 and C2. Further, a step portion 13 is formed between the outer edge of the dielectric layer 12 and the outer edge of the upper conductive layer 14. By having the side surface 12a of the dielectric layer 12 protrude from the side surface 14a of the upper conductive layer 14 in this way, a creepage distance between the upper conductive layer 14 and the lower conductive layer 10 is extended, and thereby a short circuit between the conductive layers is suppressed. The step portion 13 may be formed over the entire circumference of the capacitor structures C1 and C2 (that is, the entire circumference of the dielectric layer 12 and the entire circumference of the upper conductive layer 14) when viewed from the first main surface 1a side or may be formed in a part thereof.

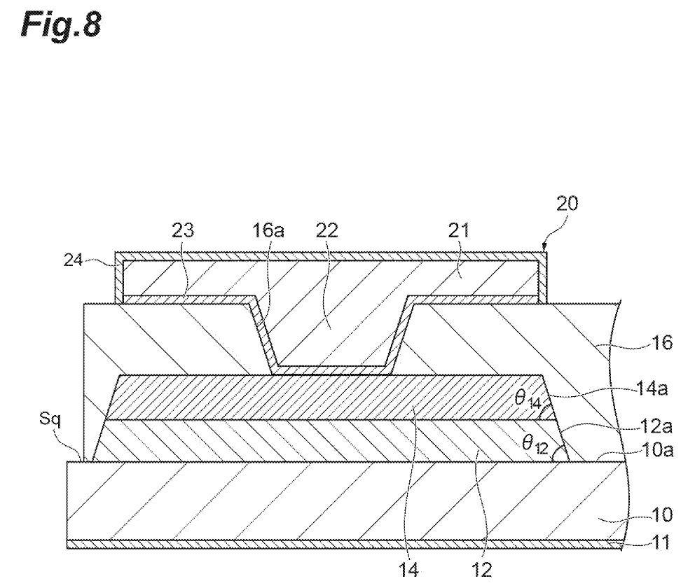

In the form shown in FIG. 8, both the side surface 12a of the dielectric layer 12 and the side surface 14a of the upper conductive layer 14 are inclined with respect to the stacking direction. The side surface 12a of the dielectric layer 12 is inclined over the entire circumference of the dielectric layer 12, and the side surface 14a of the upper conductive layer 14 is inclined over the entire circumference of the upper conductive layer 14. More specifically, an inclination angle θ₁₂ of the side surface 12a of the dielectric layer 12 and an inclination angle θ₁₄ of the side surface 14a of the upper conductive layer 14 are the same, and the side surface 12a of the dielectric layer 12 and the side surface 14a of the upper conductive layer 14 are flush with each other. The dielectric layer 12 and the upper conductive layer 14 have a cross-sectional dimension in a cross-section orthogonal to the stacking direction that gradually increases as they approach the lower conductive layer 10, and a width thereof gradually increases in the cross-section shown in FIG. 8. In this case, when viewed from the first main surface 1a side, an outer edge of the dielectric layer 12 is located outside an outer edge of the upper conductive layer 14, and the outer edge of the dielectric layer 12 constitutes an outer edge of the capacitor structures C1 and C2. Such an inclination of the side surface 12a of the dielectric layer 12 and the side surface 14a of the upper conductive layer 14 can be formed in patterning (for example, dry etching) in a state where the dielectric layer 12 and the upper conductive layer 14 are overlapped. Since the side surface 12a of the dielectric layer 12 and the side surface 14a of the upper conductive layer 14 are inclined, an area of the side surface 12a of the dielectric layer 12 and the side surface 14a of the upper conductive layer 14 is increased compared to a case where they are not inclined, and thereby improvement in adhesion between the dielectric layer 12 and the upper conductive layer 14 and the protective layer 16 is achieved.

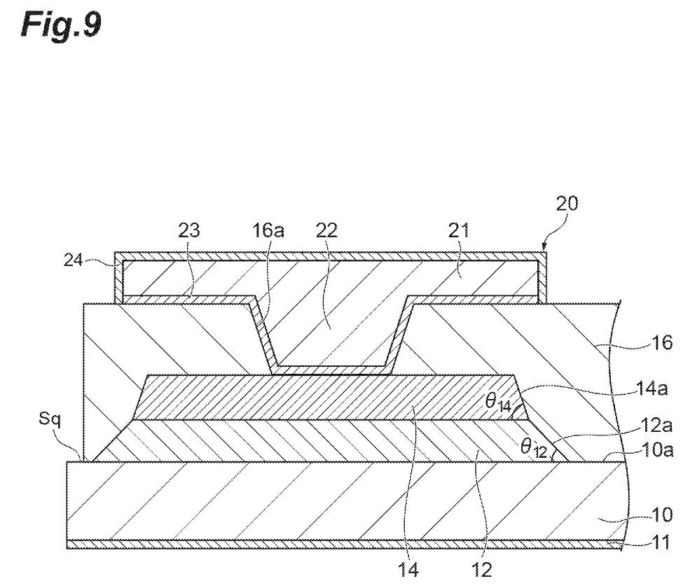

The form shown in FIG. 9 is different from the form shown in FIG. 8 in that an inclination angle θ₁₂ of the side surface 12a of the dielectric layer 12 and an inclination angle θ₁₄ of the side surface 14a of the upper conductive layer 14 are different. More specifically, the inclination angle θ₁₂ of the side surface 12a of the dielectric layer 12 is larger than the inclination angle θ₁₄ of the side surface 14a of the upper conductive layer 14. The inclination angle θ₁₂ of the side surface 12a of the dielectric layer 12 and the inclination angle θ₁₄ of the side surface 14a of the upper conductive layer 14 are mainly determined by etching conditions and layer materials. For example, the inclination angle θ₁₂ of the side surface 12a of the dielectric layer 12 constituted by barium titanate is smaller than the inclination angle θ₁₄ of the side surface 14a of the upper conductive layer 14 constituted by Ni, which is less likely to be etched than barium titanate.

In a cross-section parallel to the stacking direction of the dielectric layer 12 and the upper conductive layer 14 shown in FIGS. 4 and 7 to 9, a length of a contact surface (upper surface in the figures) of the dielectric layer 12 that contacts the upper conductive layer 14 is equal to or greater than a length of a contact surface of the upper conductive layer 14 that contacts the dielectric layer 12. That is, in the forms shown in FIGS. 4, 8 and 9, the length of the contact surface of the dielectric layer 12 that contacts the upper conductive layer 14 and the length of the contact surface of the upper conductive layer 14 that contacts the dielectric layer 12 are the same, and in the form shown in FIG. 7, the length of the contact surface of the dielectric layer 12 that contacts the upper conductive layer 14 is longer than the length of the contact surface of the upper conductive layer 14 that contacts the dielectric layer 12.

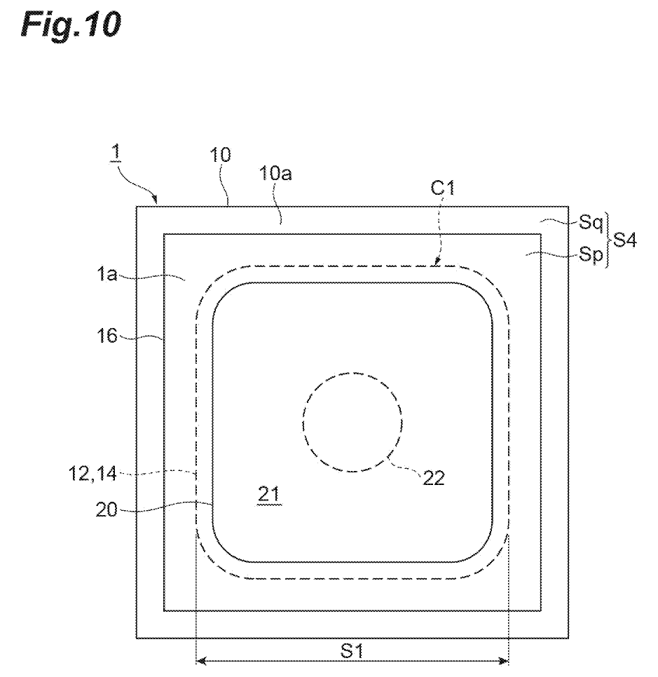

The electronic component 1 is not limited to a form including two capacitor structures, and may be a form including only one capacitor structure. FIG. 10 shows an electronic component 1 including only one capacitor structure C1. In the electronic component 1 shown in FIG. 10, when viewed from the first main surface 1a side, the lower conductive layer 10 has a substantially square shape. A remaining region of the capacitor region S1 on the main surface 10a of the lower conductive layer 10 serves as an exposed region S4, and both an outer peripheral region Sq and an inner peripheral region Sp of the exposed region S4 surround the entire circumference of the capacitor region S1. Then, the main surface 10a of the lower conductive layer 10 in the outer peripheral region Sq exposed from the protective layer 16 has the surface state shown in FIG. 5 (that is, a roughened surface) or the surface state shown in FIG. 6 (that is, protrusions are provided). In the electronic component 1 shown in FIG. 10, similarly to the forms shown in FIGS. 5 and 6, the end face 10c of the lower conductive layer 10 may be a roughened surface.

The number of capacitor structures C1 and C2 included in the electronic component 1 may be three or more. In this case, the electronic component 1 further includes a capacitor structure similar to the capacitor structures C1 and C2, and three or more capacitor structures are connected in parallel.

What is claimed is:

1. An electronic component comprising:
a lower conductive layer having a main surface, and, when viewed from the main surface side, having an outer peripheral region located at an outer edge, an inner peripheral region located on an inner peripheral side of the outer peripheral region, and a capacitor region surrounded by the inner peripheral region;
a dielectric layer and an upper conductive layer arranged in order on the lower conductive layer in the capacitor region; and
a resin layer integrally covering the dielectric layer and the upper conductive layer in the capacitor region and the lower conductive layer exposed from the dielectric layer and the upper conductive layer in the inner peripheral region,
wherein an arithmetic mean roughness of the lower conductive layer in the outer peripheral region is greater than an arithmetic mean roughness of the lower conductive layer in the capacitor region.

2. The electronic component according to claim 1, wherein when an arithmetic mean roughness of the lower conductive layer in the outer peripheral region is Ra1 and an arithmetic mean roughness of the lower conductive layer in the capacitor region is Ra2, 10 < Ra1/Ra2 < 5000 is satisfied.

3. An electronic component comprising:
a lower conductive layer having a main surface, and, when viewed from the main surface side, having an outer peripheral region located at an outer edge, an inner peripheral region located on an inner peripheral side of the outer peripheral region, and a capacitor region surrounded by the inner peripheral region;
a dielectric layer and an upper conductive layer arranged in order on the lower conductive layer in the capacitor region; and
a resin layer that integrally covering the dielectric layer and the upper conductive layer in the capacitor region and the lower conductive layer exposed from the dielectric layer and the upper conductive layer in the inner peripheral region,
wherein the lower conductive layer has a protrusion on the main surface in the outer peripheral region.

4. The electronic component according to claim 3, wherein the capacitor region has a rectangular shape, and the protrusion is located in the outer peripheral region at a corner portion of the capacitor region.

5. The electronic component according to claim 3, wherein a height of the protrusion is 1μm to 6μm.

6. The electronic component according to claim 3, further comprising a recess on the main surface of the lower conductive layer in the outer peripheral region.

7. The electronic component according to claim 6, wherein a depth of the recess is 1μm to 6μm.

8. The electronic component according to claim 1, wherein an arithmetic mean roughness of the lower conductive layer in the outer peripheral region is greater than an arithmetic mean roughness of an end face of the lower conductive layer.

9. The electronic component according to claim 1, wherein the arithmetic mean roughness of the lower conductive layer in the capacitor region is smaller than an arithmetic mean roughness of an end face of the lower conductive layer.

10. The electronic component according to claim 1, wherein the lower conductive layer includes a plurality of the capacitor regions surrounded by the inner peripheral region and provided adjacent to each other, and an intermediate region interposed between the plurality of capacitor regions,
wherein the lower conductive layer extends to straddle the plurality of capacitor regions and the intermediate region,
wherein in each of the plurality of capacitor regions, the dielectric layer and the upper conductive layer are arranged in order on the lower conductive layer, and
wherein the resin layer integrally covering the dielectric layer and the upper conductive layer in each of the plurality of capacitor regions, and the lower conductive layer exposed from the dielectric layer and the upper conductive layer in the inner peripheral region and the intermediate region.

11. The electronic component according to claim 10, wherein an outer shape of the dielectric layer and an outer shape of the conductive layer in each of the plurality of capacitor regions are identical with each other.

12. The electronic component according to claim 1, wherein a surface of the lower conductive layer opposite to the main surface is constituted by a material containing Au as a main component.

13. The electronic component according to claim 1, wherein the lower conductive layer is constituted by a metal foil.

14. The electronic component according to claim 1, wherein the upper conductive layer is constituted by Ni.

15. A module comprising the electronic component according to claim 1.
